(19) United States
(12) Patent Application Publication
(10) Pub. No.: US 2026/0159374 A1
(43) Pub. Date: Jun. 11, 2026

(54) CONNECTION ASSEMBLY FOR MEMS, SCANNING MIRROR, AND LIDAR SYSTEM

(71) Applicant: inSync Resonance Inc, Fremont, CA (US)

(72) Inventor: Qin ZHOU, Fremont, CA (US)

(21) Appl. No.: 18/970,963

(22) Filed: Dec. 6, 2024

(51) Int. Cl. B81B 3/00; G01S 7/481

(52) U.S. Cl. CPC B81B 3/0072; G01S 7/4817; B81B 2201/042; B81B 2203/0154; B81B 2203/0163

(57) ABSTRACT

A connection assembly for a MEMS, a scanning mirror, and a LiDAR system are provided. The connection assembly for the MEMS includes two fixing piles arranged opposite to each other and at least one connection beam arranged between the two fixing piles. Each of the at least one connection beam at least includes a first bending portion.

### FIELD

The present disclosure relates to the technical field of micro-electro-mechanical systems (MEMS), and more particularly, to a connection assembly for a MEMS, a scanning mirror, and a laser detection and ranging (LiDAR) system.

### BACKGROUND

In a MEMS, some mechanical structures are designed to provide degrees of freedom of motion for other structures when mechanical deformation occurs, such as a T-shaped rod. FIG. 1 is a schematic structural view of the T-shaped rod of the MEMS in the related art. As illustrated in FIG. 1, a core structure of the T-shaped rod is a straight dual clamping beam that provides a restoring force when deformed. In particular, as illustrated in FIG. 2, when the dual clamping beam is deformed by a pulling force in a plane where the dual clamping beam is located, the restoring force provided according to the dual clamping beam is related to deformation of the dual clamping beam, and a coefficient of recovery between the restoring force and the deformation is nonlinear. A non-linear term mainly arises from a tension increased due to an elongation of a horizontal rod during the deformation, which therefore generates an additional restoring force.

A design of the T-shaped rod in the related art cannot meet actual product requirements. In addition, typically, the above-mentioned connection assembly is fixedly connected to a substrate of the MEMS by means of fixing piles at two ends of the connection assembly. In some cases, each of the above-mentioned fixing piles may have a bonding structure. The bonding structure includes a bonding pad integrally formed with the connection beam and a support post formed at the substrate of the MEMS. The connection assembly is fixedly connected to the substrate of the MEMS through bonding the above-mentioned bonding pad to the support post. However, in response to a deformation of the connection beam, a large stress is introduced at a bonding interface, which in turn affects bonding reliability and homogeneity of bonding stiffness.

### SUMMARY

The present disclosure aims to solve at least one of the technical problems in the related art. To this end, a connection assembly for a MEMS, a scanning mirror, and a LiDAR system are provided according to the present disclosure, so as to better meet requirements of practical products for the connection assembly.

In a first aspect, a connection assembly of a MEMS is provided according to the present disclosure. The connection assembly for the MEMS includes two fixing piles arranged opposite to each other, and at least one connection beam arranged between the two fixing piles. Each of the at least one connection beam at least includes a first bending portion.

In the embodiments of the present disclosure, since the first bending portion is arranged at the connection assembly, a tensile stress of the connection beam is unlikely to rapidly increase even if a large displacement occurs in a direction opposite to a protrusion direction of the first bending portion. Therefore, the first bending portion is prevented from fracturing the connection beam in response to rapidly reaching a fracture stress of silicon, which improves resistance to fracture of the first bending portion and allows movement over a wide range. In addition, even-order non-linear terms can be introduced into a coefficient of recovery of the connection assembly to achieve controllable nonlinearity.

In some embodiments, the first bending portion extends from one fixing pile of the two fixing piles to the other fixing pile of the two fixing piles.

In some embodiments, each of the at least one connection beam further includes a first straight segment and a second straight segment that have a same length. Each of the at least one connection beam is connected to the two fixing piles through the first straight segment and the second straight segment, respectively.

In some embodiments, each of the at least one connection beam further includes a second bending portion and a third bending portion. Each of the at least one connection beam is connected to the two fixing piles through the second bending portion and the third bending portion, respectively.

In some embodiments, a curvature of the second bending portion and a curvature of the third bending portion are the same and smaller than a curvature of the first bending portion; and/or the second bending portion and the third bending portion have a bending direction opposite to a bending direction of the first bending portion.

In some embodiments, the at least one connection beam includes two connection beams arranged symmetrically with respect to a center plane, and the two connection beams sharing the two fixing piles. Or each of the two fixing piles includes two sub-fixing piles, the two sub-fixing piles are configured to support the two connection beams.

In some embodiments, the connection assembly further includes a connection rod connected to the first bending portion. The first bending portion protrudes in a direction away from the connection rod.

In some embodiments, the connection rod has two ends each connected to a corresponding connection beam of the at least one connection beam.

In some embodiments, the connection assembly further includes a mass block, the connection beam being configured to support the mass block.

In some embodiments, each of the two fixing pile includes a bonding pad and a support post formed at a substrate of the MEMS. The bonding pad, the at least one connection beam and the support post are formed as one piece, and a plurality of columnar structures are formed at a first bonding surface of the bonding pad close to the support post, and/or a plurality of columnar structures are formed at a second bonding surface of the support post close to the bonding pad.

In some embodiments, the plurality of columnar structures are obtained through cutting in a first direction, and/or the plurality of columnar structures are obtained through cutting in a second direction, the first direction being an extension direction of the at least one connection beam, and the second direction being at a predetermined angle to the first direction.

In a second aspect, a scanning mirror is further provided according to the embodiments of the present disclosure. The scanning mirror includes torsion springs arranged in an array on a MEMS, a connection assembly arranged between any two adjacent torsion springs of the torsion springs. The two adjacent torsion springs are connected by the connection assembly, and in response to the two adjacent torsion springs being twisted, the connection assembly is stretched to provide a torque that is non-linearly recovered. Each of the torsion springs includes two fixing components arranged opposite to each other and a beam structure arranged between the two fixing components. The beam structure is provided with a first connection plate, the two ends of the connection assembly in a stretching direction being connected to two first connection plates of the two adjacent torsion springs, respectively, and a reflection mirror is arranged at a surface of the first connection plate. Each of the two first connection plates has an opening formed at an end close to a connection assembly. The connection assembly includes two fixing piles arranged opposite to each other, at least one connection beam arranged between the two fixing piles, and a connection rod. Each of the at least one connection beam at least includes a first bending portion, the connection rod being connected to the two first connection plates arranged at two sides of the opening by the two connection beams, respectively. The scanning mirror further includes a drive component configured to drive the torsion springs arranged in the array to twist synchronously.

In some embodiments, the first bending portion extends from one fixing pile of the two fixing piles to the other fixing pile of the two fixing piles.

In some embodiments, each of the at least one connection beam further includes a first straight segment and a second straight segment that have a same length. Each of the at least one connection beam is connected to the two fixing piles through the first straight segment and the second straight segment, respectively.

In some embodiments, each of the at least one connection beam further includes a second bending portion and a third bending portion. Each of the at least one connection beam is connected to the two fixing piles through the second bending portion and the third bending portion, respectively.

In some embodiments, a curvature of the second bending portion and a curvature of the third bending portion are the same and smaller than a curvature of the first bending portion; and/or the second bending portion and the third bending portion have a bending direction opposite to a bending direction of the first bending portion.

In some embodiments, the at least one connection beam includes two connection beams arranged symmetrically with respect to a center plane, and the two connection beams sharing the two fixing piles. Or each of the two fixing piles includes two sub-fixing piles, the two sub-fixing piles are configured to support the two connection beams.

In some embodiments, the connection assembly further includes a connection rod connected to the first bending portion. The first bending portion protrudes in a direction away from the connection rod.

In some embodiments, the connection rod has two ends each connected to a corresponding connection beam of the at least one connection beam.

In a third aspect, a LiDAR system is further provided according to the embodiments of the present disclosure. The LiDAR system includes a light source, a photodetector, a processor, and the scanning mirror. A laser beam emitted by the light source is reflected to a target region by the scanning mirror. The photodetector is configured to receive at least part of reflected light from the target region and convert the at least part of the reflected light into an electrical signal. The processor is configured to obtain a laser point cloud from the target region based on the electrical signal.

The connection assembly for the MEMS, the scanning mirror, and the LiDAR system are provided according to the embodiments of the present disclosure. Since the first bending portion arranged at the connection assembly, the tensile stress of the connection beam is unlikely to rapidly increase even if the large displacement occurs in the direction opposite to the protrusion direction of the first bending portion. Therefore, the first bending portion is prevented from fracturing the connection beam in response to rapidly reaching the fracture stress of silicon, which improves the resistance to fracture of the first bending portion and allows the movement over the wide range. In addition, the even-order non-linear terms can be introduced into the coefficient of recovery of the connection assembly to achieve the controllable nonlinearity. The connection assembly according to the above-mentioned embodiments is applied in the spring, the scanning mirror, and the LiDAR system, and thus each of the spring, the scanning mirror, and the LiDAR system is of the same design idea as the connection assembly and provides a technical effect corresponding to that of the connection assembly. Reference can be made to contents described in the above-mentioned embodiments.

Additional aspects and advantages of the present disclosure will be provided at least in part in the following description, or will become apparent at least in part from the following description, or can be learned from practicing of the present disclosure.

### BRIEF DESCRIPTION OF THE DRAWINGS

The above and/or additional aspects and advantages of the present disclosure will become more apparent and more understandable from the following description of embodiments taken in conjunction with the accompanying drawings.

FIG. 1 is a schematic structural view of a T-shaped rod of an MEMS in the related art.

FIG. 2 is a schematic view of the T-shaped rod, according to an embodiment illustrated in FIG. 1, subjected to a force.

FIG. 3 is a simplified schematic structural view of a T-shaped rod in the related art.

FIG. 4 is a schematic structural view of a connection assembly according to some embodiments of the present disclosure.

FIG. 5 is a schematic view of the connection assembly, according to the embodiment illustrated in FIG. 4, subjected to a force.

FIG. 6 is a schematic structural view of a connection assembly according to some embodiments of the present disclosure.

FIG. 7 is a schematic structural view of a connection assembly according to some embodiments of the present disclosure.

FIG. 8 is a schematic structural view of a connection assembly according to some embodiments of the present disclosure.

FIG. 9 is a schematic structural view of a connection assembly according to some embodiments of the present disclosure.

FIG. 10 is a schematic structural view of a connection assembly according to some embodiments of the present disclosure.

FIG. 11 is a schematic structural view of a connection assembly according to some embodiments of the present disclosure.

FIG. 12 is a schematic structural view of a connection assembly according to some embodiments of the present disclosure.

FIG. 13 is a schematic structural view of a method for arranging a mass block according to some embodiments of the present disclosure.

FIG. 14 is a schematic structural view of a method for arranging a mass block according to some embodiments of the present disclosure.

FIG. 15 is a schematic structural view of a fixing pile obtained through a bonding process according to an embodiment of the present disclosure.

FIG. 16 is a schematic force view of a cross section, taken in direction A-A, of the fixing pile according to the embodiment illustrated in FIG. 15.

FIG. 17 is a schematic force view of a cross section, taken in direction A-A, of a support post with a center region removed according to an embodiment of the present disclosure.

FIG. 18 is a schematic view of a cross section, taken in direction A-A, of a defective fixing pile according to an embodiment of the present disclosure.

FIG. 19 is a schematic view of a cross section, taken in direction A-A, of a fixing pile bonded after performing cutting on a support post of the present disclosure.

FIG. 20 is a schematic view of a cross section, taken in direction A-A, of a fixing pile bonded after performing cutting on a bonding pad of the present disclosure.

FIG. 21 is a schematic view of a cross section, taken in direction A-A, of a bonded defective fixing pile according to an embodiment of the present disclosure.

FIG. 22 is a schematic view of a cross section of a columnar structure according to some embodiments of the present disclosure.

FIG. 23 is a schematic view of a cross section of a columnar structure according to some embodiments of the present disclosure.

FIG. 24 is a schematic view of a cross section of a columnar structure according to some embodiments of the present disclosure.

FIG. 25 is a schematic view of a cross section of a columnar structure according to an embodiment of the present disclosure.

FIG. 26 is a schematic structural view of a spring (connection assembly) according to some embodiments of the present disclosure.

FIG. 27 is a schematic structural view of a spring assembly (connection assembly) according to some embodiments of the present disclosure.

FIG. 28 is a schematic structural view of a scanning mirror according to some embodiments of the present disclosure.

FIG. 29 is a schematic view of a specific structure in the embodiment illustrated in FIG. 17.

FIG. 30 is a schematic structural view of a LiDAR system according to some embodiments of the present disclosure.

FIG. 31 is a schematic structural view of a LiDAR system according to some embodiments of the present disclosure.

### DETAILED DESCRIPTION

Embodiments of the present disclosure will be described in detail below with reference to examples thereof as illustrated in the accompanying drawings, throughout which same or similar elements, or elements having same or similar functions, are denoted by same or similar reference numerals. The embodiments described below with reference to the drawings are illustrative, and are only intended to explain, rather than limit, the present disclosure.

In various application scenarios and products of an IEMS, a T-shaped rod is a frequently used mechanical structure, which is equivalent to a spring and can provide degrees of freedom of motion for other structures when mechanical deformation occurs. A core structure of the T-shaped rod is a straight connection beam that provides a restoring force when deformed. For example, when the T-shaped rod is applied in a scanning mirror, the freedom of motion provided according to the connection assembly can allow the scanning mirror to move reciprocally in a predetermined region. Or, when the T-shaped rod is applied in an accelerometer, a mass block is arranged at the connection beam. When an acceleration occurs, the mass block is displaced due to inertia, driving the connection beam to be deformed. In addition, the principle of piezoelectric effect or the principle of capacitance effect can be used to measure a displacement of the mass block to determine a magnitude of the acceleration. Or, when the T-shaped rod is applied in a gyroscope, the mass block is arranged at the connection beam and driven to vibrate along an original drive shaft. If a rotation occurs, Coriolis force results in a small displacement on an induction shaft perpendicular to the original drive shaft. An angular velocity during the rotation can be calculated based on capacitance effect or piezoresistive effect. It should be noted that, since the connection beam is connected between two fixing piles, i.e., the connection beam is subjected to clamping forces from the two fixing piles, the connection beam can also be referred to as a dual clamping beam.

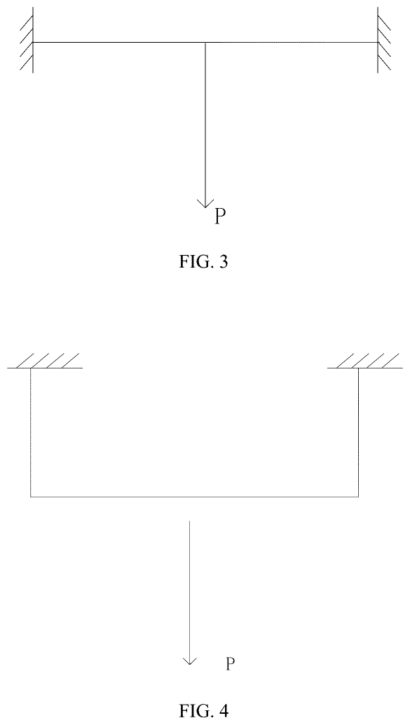

FIG. 3 is a simplified schematic structural view of a T-shaped rod in the related art. As illustrated in FIG. 3, a restoring force provided according to the T-shaped rod is related to a deformation of the T-shaped rod. A relationship between the restoring force F and the deformation x can be shown in the following formula:

$$F = k x + {k}_{3} {x}^{3} .$$

In the equation, the deformation x is also a displacement of the T-shaped rod that occurs when the T-shaped rod is subjected to a pulling force P. A linear term k and a non-linear term k₃ in the above-mentioned formula are expressed as:

$$k = \frac{192 E I}{{L}^{3}} ; and$$

$${k}_{3} = \frac{288 E A}{25 {L}^{3}} ,$$

respectively,

where E represents a modulus of elasticity, I represents a moment of inertia of a cross-section of the connection beam, A represents a cross-sectional area of the connection beam, and L represents a length of the connection beam.

Therefore, in the related art, since the straight connection beam is used in the T-shaped rod, a fracture stress of silicon is likely to be reached with a rapid increase in a tensile stress of the horizontal rod when a large displacement occurs, and thus the connection beam is fractured. In this way, a movement range of the T-shaped rod is limited. In addition, because of symmetry of the straight connection beam, a non-linear term in a coefficient of recovery of the straight connection beam only includes an odd-order term k₃. However, in some applications, to achieve some engineering effects, an even-order non-linear term is desired, such as in the application of the scanning mirror mentioned above.

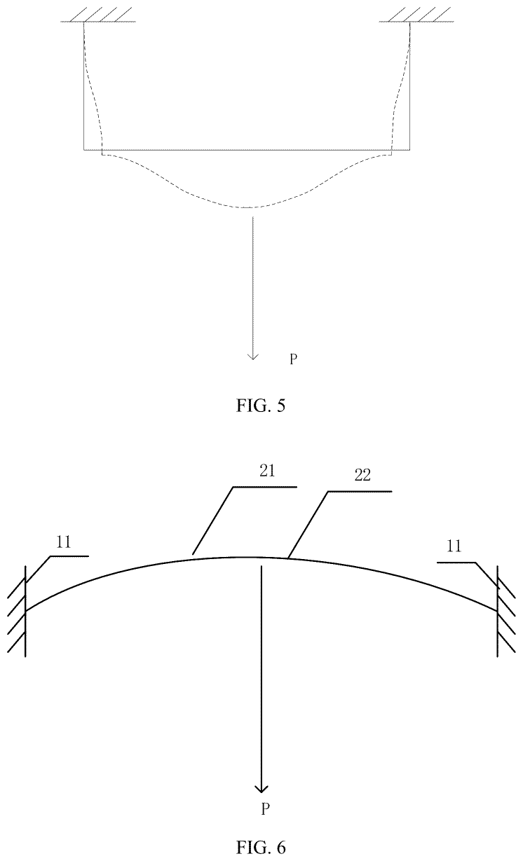

To remove limitations on the movement range of the connection assembly, a connection assembly having an “elbow” can be designed. For example, as illustrated in FIG. 4, on a basis of the original straight connection beam, the “elbow” is provided, which can accommodate horizontal movements in a plane where the connection assembly is located, and relieve the tensile stress caused by the large displacement, as illustrated in FIG. 5. This design scheme can significantly increase the movement range of the connection assembly and reduce the non-linear term, but the design scheme is also likely to lead to excessive relaxation of the freedom of motion of the structure in other directions, resulting in a decrease in motion stiffness. In addition, a problem of lack of an even-order term in the non-linear term of the coefficient of recovery is not solved.

A connection assembly for a MEMS is provided according to the embodiments of the present disclosure. Reference can be made to FIG. 6 to FIG. 14, which illustrate connection assemblies in various forms in the embodiments of the present disclosure. The connection assembly for the MEMS according to the embodiments of the present disclosure includes two fixing piles 11 arranged opposite to each other and at least one connection beam 21 arranged between the two fixing piles 11. Each connection beam 21 includes at least one first bending portion. That is, each connection beam 21 at least includes a first bending portion 22 as illustrated in FIG. 6.

In some cases, the above-mentioned connection assembly may include only the first bending portion 22.

In an exemplary embodiment of the present disclosure, as illustrated in FIG. 6, the first bending portion 22 extends from one fixing pile 11 to the other fixing pile 11. That is, the first bending portion 22 covers an entire region where the connection beam is located. In some embodiments, the first bending portion 22 has a same curvature at any position. That is, the first bending portion 22 may correspond to a segment of a circular arc.

In the embodiment illustrated in FIG. 6, the connection beam 21 is arranged symmetrically with respect to a midperpendicular plane of a connection line of the two fixing piles 11. That is, a left part and a right part of the connection beam 21 are arranged symmetrically.

With the structure of the connection assembly according to the embodiments of the present disclosure, since the first bending portion 22 is arranged at the connection assembly, a tensile stress of the connection beam is unlikely to rapidly increase even if a large displacement occurs in a direction opposite to a protrusion direction of the first bending portion 22. Therefore, the first bending portion is prevented from fracturing the connection beam in response to rapidly reaching a fracture stress of silicon, which improves resistance to fracture of the first bending portion and allows movement over a wide range.

In addition, for this design, a second-order non-linear term can also be added to the coefficient of recovery to meet needs of some applications. In an exemplary embodiment of the present disclosure, a left half of the connection beam 21, i.e., a shape of the segment 0<x<L/2, can be expressed as:

$${y}_{0} = \frac{{a}_{1} x}{L} + \frac{{a}_{2} {x}^{2}}{{L}^{2}} + \frac{{a}_{3} {x}^{3}}{{L}^{2}} .$$

A right half of L/2<x<L also has a symmetrical shape, where a₁, a₂, and a₃ are predetermined constants related to an initial shape of the connection beam.

Therefore, it can be deduced that a relationship between a restoring force F and a deformation x can be expressed by the following equation:

F=kx+k₂x²+k₃x³, where

$$k = \frac{192 E I + E A {a}^{2}}{{L}^{3}} ,$$

$${k}_{2} = \frac{36 E A a}{5 {L}^{3}} , and$$

$${k}_{3} = \frac{288 E A}{25 {L}^{3}} .$$

In the above-mentioned equation,

$$a = 2 {a}_{1} + {a}_{2} + \frac{9}{20} {a}_{3} .$$

In addition, as mentioned above, E represents the modulus of elasticity, I represents the moment of inertia of the cross-section of the connection beam, A represents the cross-sectional area of the connection beam, and L represents the length of the connection beam.

The above-mentioned relationship between the restoring force F and the deformation x reveals that the coefficient of recovery includes a second-order non-linear term related to a shape of the connection beam. The second-order non-linear term indicates that the restoring force of the connection beam having the first bending portion is asymmetric during a deformation, which is useful in some application scenarios such as the scanning mirror mentioned above. In the technical solutions according to the embodiments of the present disclosure, a controllable non-linear term can be realized.

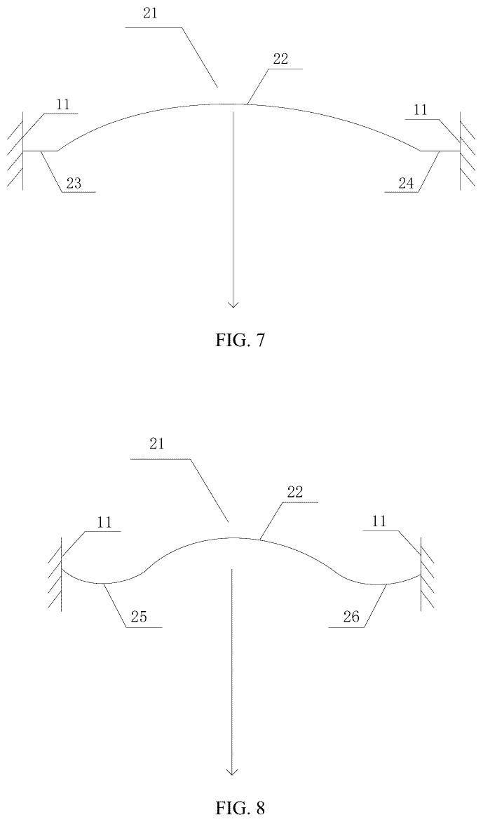

Further, the embodiments of the present disclosure further provide the following embodiments illustrated in FIG. 7 to FIG. 12. Connection beams of different shapes are provided in the following embodiments to enable a₁, a₂ and a₃ to take different values, and thus more values of k₁, k₂, and k₃ can be obtained. In this way, a range of parameters in the implementations according to the embodiments of the present disclosure is extended, providing a wider range of application scenarios.

In some embodiments, for example, as illustrated in FIG. 7, in a case where each connection beam includes one bending portion, i.e., the first bending portion, the connection beam may further include two straight segments that may have a same length. In an exemplary embodiment of the present disclosure, as illustrated in FIG. 7, the connection beam further includes a first straight segment 23 and a second straight segment 24. The one first bending portion 22 mentioned above is connected to the two fixing piles 11 by the first straight segment 23 and the second straight segment 24, respectively.

In some embodiments, for example, as illustrated in FIG. 8, in a case where each connection beam includes one first bending portion 22, the connection beam may further include two bending portions, i.e., a second bending portion 25 and a third bending portion 26. The one first bending portion 22 mentioned above is connected to the two fixing piles 11 by the second bending portion 25 and the third bending portion 26, respectively.

In addition, specific lengths and specific curvatures of the two bending portions mentioned above, i.e., the second bending portion 25 and the third bending portion 26, are not limited.

In some embodiments, a curvature of the second bending portion 25 and a curvature of the third bending portion 26 are the same. In addition, the second bending portion 25 and the third bending portion 26 may have the curvature smaller than, equal to, or greater than a curvature of the first bending portion 22, depending on specific application scenarios and requirements. The embodiments of the present disclosure are not limited in this regard.

In some embodiments, the second bending portion 25 and the third bending portion 26 may be set to have a bending direction the same as or opposite to a bending direction of the first bending portion 22.

In some embodiments, the second bending portion 25 and the third bending portion 26 may be set to have a length of half that of the first bending portion 22.

In some embodiments, the connection beam may include the first bending portion 22, the second bending portion 25, the third bending portion 26, the first straight segment 23, and the second straight segment 24 that are connected to each other. The connection beam may be connected to the two fixing piles 11 by the second bending portion 25 and the third bending portion 26. In this case, in a direction from one fixing pile 11 to the other fixing pile 11, the first bending portion 22, the first straight segment 23, and the second straight segment 24 are located between the second bending portion 25 and the third bending portion 26.

In some embodiments, the connection beam may also be connected to the two fixing piles 11 by the first straight segment 23 and the second straight segment 24. In this case, in the direction from one fixing pile 11 to the other fixing pile 11, the first bending portion 22, the second bending portion 25, and the third bending portion 26 are located between the first straight segment 23 and the second straight segment 24.

With regard to an arrangement of the connection beam according to any of the embodiments of the present disclosure, the connection beam can be arranged symmetrically with respect to the midperpendicular plane of the connection line of the two fixing piles, in such a manner that a calculation equation between the restoring force of the connection beam and the deformation of the connection beam can be simplified.

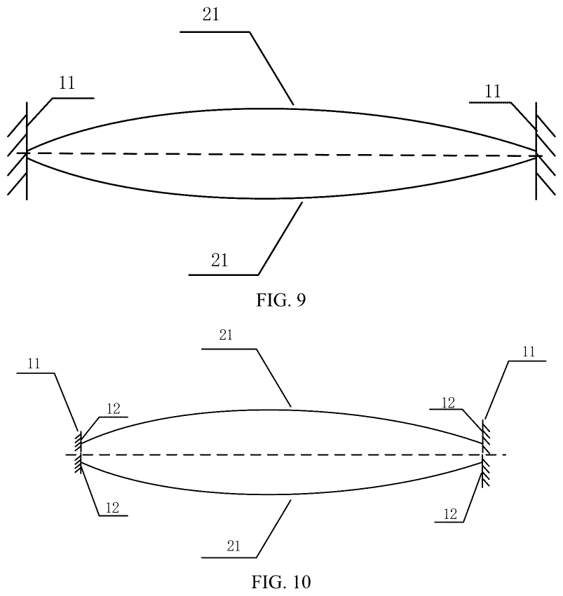

Unlike the above-mentioned arrangement of only one connection beam 21, more connection beams 21 may be provided according to the embodiments of the present disclosure. For example, two connection beams 21 may be provided. FIG. 9 is a schematic structural view of two connection beams according to an embodiment of the present disclosure. As illustrated in FIG. 9, two connection beams 21 are provided. The two connection beams 21 are arranged symmetrically with respect to a center plane. In the above-mentioned case where the two connection beams 21 are provided, the two connection beams 21 may share the fixing piles 11. That is, the two fixing piles 11 arranged at two ends may still be included.

Or, in some embodiments, as illustrated in FIG. 10, the fixing pile 11 at each end may be arranged to include two sub-fixing piles 12. The two sub-fixing piles 12 are configured to support the two connection beams 21.

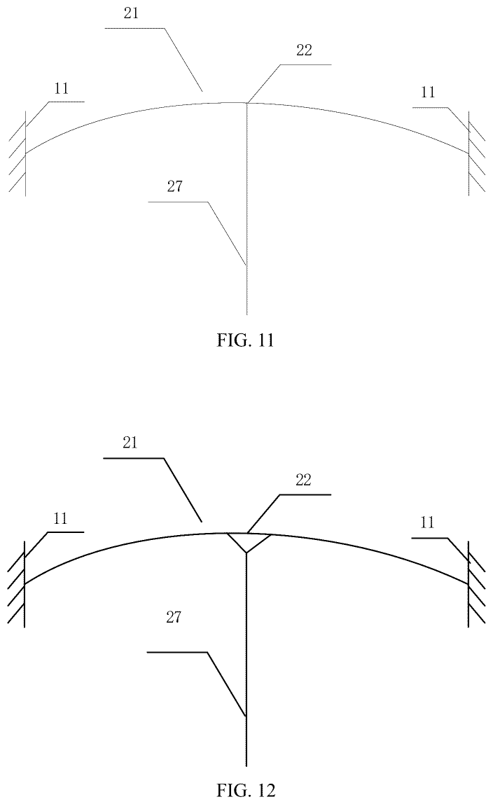

In some embodiments, to provide the degrees of freedom of motion by the connection assembly for other structures, a connection rod can be arranged to facilitate a connection to the other structures. In an exemplary embodiment of the present disclosure, as illustrated in FIG. 11, on a basis of the connection assembly according to the above-mentioned embodiments, a connection rod 27 is also provided. The connection rod 27 is connected to a middle of the above-mentioned first bending portion 22. In this way, when the connection assembly is used for a mechanical deformation and for providing the degrees of freedom of motion for the other structures, the connection rod 27 can be connected to the other structures. The connection rod 27 can be configured to drive or to be driven by the other structures.

A connection between the connection rod 27 and each connection beam 21 can be realized by one connection point or more connection points. For example, as illustrated in FIG. 12, the connection rod 27 is connected to the connection beam 21 by two connection points.

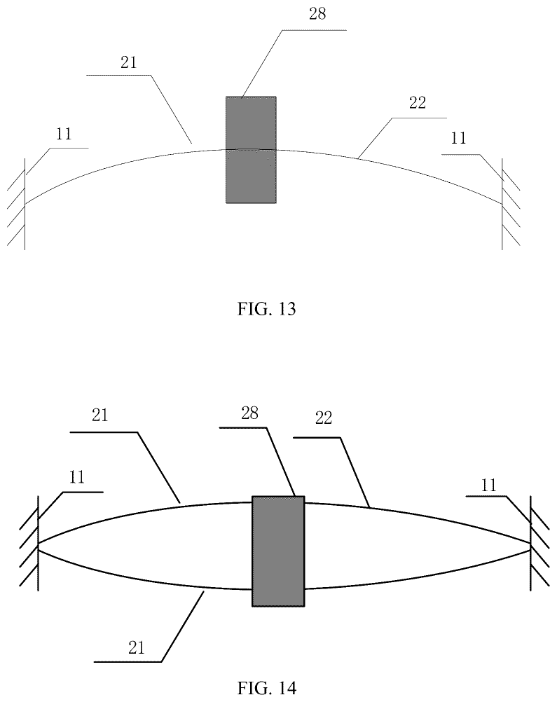

In some embodiments, based on requirements of some specific application scenarios, a mass block can be directly arranged at the connection beam without setting the connection rod to be connected to the other structures. For example, in cases of manufacturing accelerometers and gyroscopes using the connection assembly, the mass block can be directly arranged at the connection beam, in such a manner that when an acceleration or an angular velocity is measured, the acceleration or the angular velocity can be calculated directly based on a movement of the mass block arranged at the connection beam. In an exemplary embodiment of the present disclosure, as illustrated in FIG. 13, a mass block 28 is added to the structure of the connection assembly. In this way, when one connection beam 21 is provided, the one connection beam is configured to support the above-mentioned mass block 28, to meet a requirement of arranging a basic “movement-responsive member” in the accelerometer or the gyroscope. By using the principle of piezoelectric effect or the principle of capacitance effect, the magnitude of the acceleration can be determined through performing a calculation on a displacement of the above-mentioned mass block 28. By using the principle of capacitance effect or a principle of piezoresistive effect, the angular velocity during the rotation can be determined through performing a calculation on a small displacement of the mass block 28 on the induction shaft.

With the arrangement of the mass block according to the above-mentioned embodiments, the above-mentioned connection assembly is suitable to be applied in applications of accelerometers or gyroscopes, and thus corresponding technical effects can also be provided. In particular, since the first bending portion 22 is arranged at the connection assembly, the tensile stress of the connection beam is unlikely to rapidly increase even if the mass block 28 undergoes a large displacement in the direction opposite to the protrusion direction of the first bending portion 22. Therefore, the first bending portion 22 is prevented from fracturing the connection beam in response to rapidly reaching the fracture stress of silicon, which improves the resistance to fracture of the first bending portion 22 and allows the movement of the mass block 28 over a wide range.

In addition to the case illustrated in FIG. 13 in which the mass block is arranged when the connection assembly includes one connection beam, one mass block 28 may be arranged when the connection assembly includes two connection beams 21, as illustrated in FIG. 14. The one mass block 28 is connected to the two connection beams 21 simultaneously.

In some embodiments, the fixing pile 11 at each end of the connection assembly is structured to include a bonding pad integrally formed with the connection beam and a support post formed at a substrate of the MEMS. The bonding pad and the support post are bonded as an integral structure. A plurality of columnar structures are formed at a first bonding surface of the bonding pad close to the support post, and/or a plurality of columnar structures are formed at a second bonding surface of the support post close to the bonding pad.

In the embodiment, each of the plurality of columnar structures has a cross section that may of any one of an elongate shape, a circular shape, an elliptical shape, and a polygonal shape. A shape of the cross section does not affect strength and stability of a bonding interface between the bonding pad and the support post.

In some embodiments, the plurality of columnar structures are obtained through cutting in a first direction, and/or the plurality of columnar structures are obtained through cutting in a second direction. The first direction is an extension direction of the connection beam. The second direction is at a predetermined angle to the first direction.

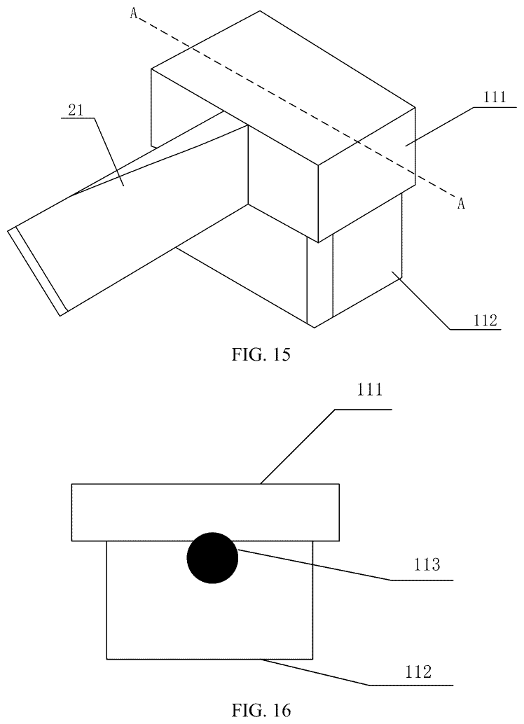

For a specific structure of the fixing pile 11 according to the embodiments of the present disclosure, reference can be made to the embodiments illustrated in FIG. 15 to FIG. 25 below. The fixing pile 11 can be applied in the connection assembly or other situations where the fixing pile is needed.

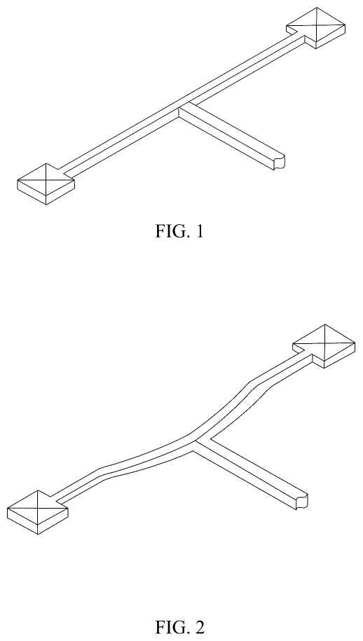

The connection assembly for the MEMS involved in the embodiments of the present disclosure, as described in the embodiments illustrated in FIG. 1 to FIG. 14 above, includes the two fixing piles 11 arranged opposite to each other and the at least one connection beam 21 arranged between the two fixing piles 11. Each of the at least one connection beam 21 is fixed to a substrate of the MEMS by the fixing pile 11. In some embodiments, the fixing pile 11 may be formed directly at the substrate of the MEMS. That is, the above-mentioned connection assembly may be obtained through a process such as etching. Alternatively, in some embodiments, the above-mentioned fixing pile 11 may be obtained through a bonding process.

FIG. 15 is a schematic structural view of a fixing pile obtained through a bonding process according to an embodiment of the present disclosure. As illustrated in FIG. 15, for the fixing pile 11 of the connection assembly, the fixing pile 11 may include the bonding pad 111 integrally formed with the connection beam 21 and the support post 112 formed at the substrate of the MEMS. The bonding pad 111 and the support post 112 are bonded as the integral structure. During a movement or a deformation of the above-mentioned connection assembly, a force applied to the connection assembly includes a pulling force in a plane of the connection beam 21 or a torque force that twists about an axis of the connection beam 21. Both the pulling force and the torque force may introduce large stresses at the bonding interface between the bonding pad 111 and the support post 112. The stresses may be concentrated in a connection region 113 between the connection beam 21 and the fixing pile 11, as may be illustrated in FIG. 16.

In addition, the bonding interface is likely to be affected by various types of manufacturing defects, resulting in cracks on the bonding surface. For a sharp crack tip, a large stress concentration factor may be generated, leading to a bond failure. Alternatively, in a case where there is no crack at a beginning, cracks may be generated in the connection assembly after a period of time due to the above-mentioned stress concentration, affecting performance of the connection assembly. In some solutions, a safety margin may be increased through enlarging an area of a bonding plane, but this leads to an increase in an area of a bonding region, sacrificing a usage area on a MEMS chip. In the embodiments of the present disclosure, a crack problem is solved through arranging a columnar structure at the bonding interface of the bonding pad 111 and/or the above-mentioned support post 112. For example, to solve the above problem, the plurality of columnar structures may be formed at the first bonding surface of the bonding pad 111 close to the support post 113, and/or the plurality of columnar structures are formed at the second bonding surface of the support post 112 close to the bonding pad 111.

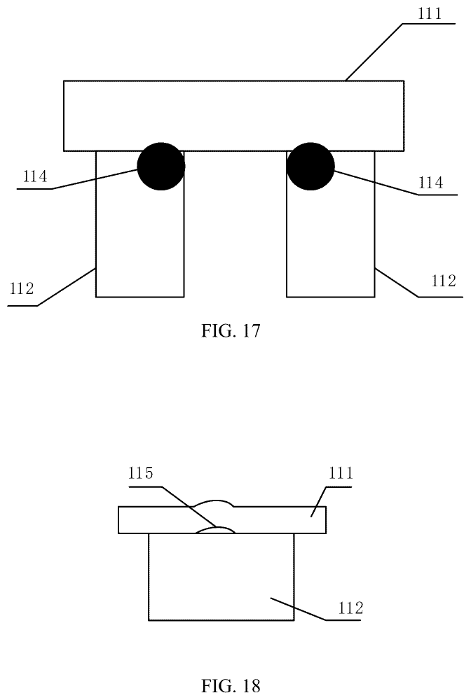

In the embodiments of the present disclosure, the force applied to the connection assembly includes the pulling force in the plane of the connection beam or the torque force that twists about the axis of the connection beam, both of which introduce the large stresses at the bonding interface between the bonding pad 111 and the support post 112. Therefore, as illustrated in FIG. 15 and FIG. 16, the maximum stress-bearing region is formed in a center region of the bonding interface of the connection region 113 close to two ends of the connection beam 21, which causes most of a load to be concentrated in the connection region 113, resulting in a bond failure in the center region of the bonding interface. In the embodiments of the present disclosure, according to an embodiment in which the columnar structure is arranged at the bonding interface, a region on the second bonding surface of the support post 112 that is nearest to the two ends of the connection beam 21 may be removed to form the columnar structure as illustrated in FIG. 17. For example, as illustrated in FIG. 17, when the center region is removed, the support post 112 is transformed from one columnar structure to two columnar structures, and the maximum stress is therefore more evenly distributed to the two bonding regions 114. Therefore, the maximum stress to be borne on the bonding interface is reduced, which improves the stability of the bonding interface. When the second bonding surface of the support post is divided into more columnar structures, the stress can be further dispersed. FIG. 17 is an example of the second bonding surface of the support post 112, but a same effect can also be achieved through forming the columnar structure at the first bonding surface of the bonding pad 111.

In addition, in a case where the bonding interface of the fixing pile 11 has a defect, e.g., as illustrated in FIG. 18, a crack 115 is formed between the bonding pad 111 and the support post 112 due to the defect, when the bonding interface is subjected to an external stress, stresses at two sharp ends of the crack 115 are concentrated and continuously damage bonding structures close thereto. Since no structure that can prevent the sharp front ends of the crack 115 from spreading is arranged at the bonding interface, the crack 115 continuously expands until overall bond of the bonding interface formed by the bonding pad 111 and the support post 112 fails.

In this embodiment, either of the bonding surfaces of the bonding pad 111 and/or the support post 112 forming the bond may be cut to solve the crack problem through arranging the columnar structure at the bonding surfaces of the bonding pad 111 and/or the support post 112.

In an exemplary embodiment of the present disclosure, to form the above-mentioned columnar structure, the plurality of columnar structures may be arranged at the bonding surface of at least one of the bonding pad 111 and the support post 112. For example, the plurality of columnar structures are formed only at the first bonding surface of the bonding pad 111 close to the support post 112, or the plurality of columnar structures are formed only at the second bonding surface of the support post 112 close to the bonding pad 111, or the plurality of columnar structures are formed at each of the first bonding surface of the bonding pad 111 and the second bonding surface of the support post 112.

When only one of the bonding pad 111 and the above-mentioned support post 112 is provided with the plurality of columnar structures, the other one of the bonding pad 111 and the above-mentioned support post 112 has a plurality of accommodation grooves. The plurality of columnar structures and the plurality of accommodation grooves are inserted into and engaged with each other in a one-to-one correspondence.

When each of the bonding pad 111 and the support post 112 is provided with the plurality of columnar structures, the plurality of columnar structures of the bonding pad 111 and the plurality of columnar structures of the support post 112 are inserted into and engaged with each other to realize bonding.

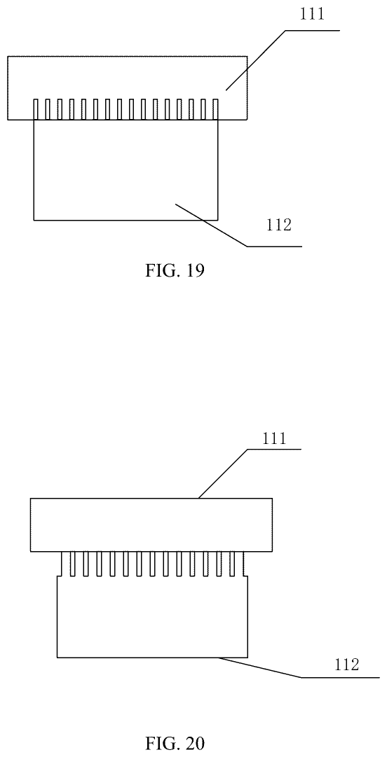

The plurality of columnar structures formed at the first bonding surface of the bonding pad 111 may be as illustrated in FIG. 19. The plurality of columnar structures formed at the second bonding surface of the support post 112 may be as illustrated in FIG. 20. For the case where the plurality of columnar structures are formed at each of the first bonding surface of the bonding pad 111 and the second bonding surface of the support post 112, the columnar structures of the two bonding surfaces should be set in correspondence. The case where the columnar structures are arranged only at a second bonding surface of the support post 112 not only benefits from an advantage of not affecting structural strength of the bonding pad 111 at the two ends of the connection beam, but also requires no stringent alignment as in the case of forming the plurality of columnar structures at each of the first bonding surface of the bonding pad 111 and the second bonding surface of the support post 112, which reduces a difficulty of bonding.

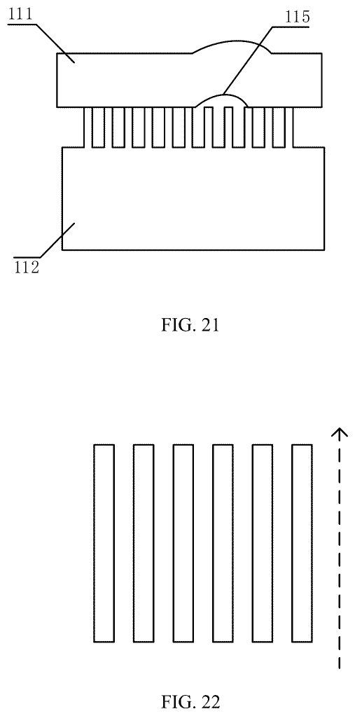

Further, according to this embodiment, the columnar structure is obtained through cutting the bonding pad 111 or the support post 112. For example, during cutting of the support post 112, the second bonding surface of the support post 112 may be cut into a plurality of columnar structures, and then bonded with the bonding pad 111. When the bonding interface of the fixing pile 11 has a defect in this case, e.g., as illustrated in FIG. 21, a sharp front end of the crack 115 damages a bonding interface of the columnar structure adjacent to the sharp front end of the crack 115. However, since there are gaps between these columnar structures, the sharp front end of the crack 115 is unable to continue to spread when encountering the gaps. Therefore, homogeneity of bonding stiffness of the bonding interface can be improved, while a spread of the defect at the bonding interface can be prevented, which greatly improves reliability of the bonding interface. As an example, FIG. 21 illustrates a formation of the columnar structures at the second bonding surface of the support post 112, but a same technical effect can also be obtained through forming the columnar structures at the first bonding surface of the bonding pad 111.

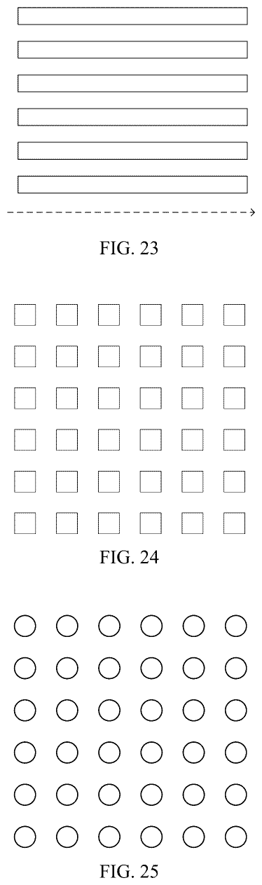

In some embodiments, the plurality of columnar structures may be obtained through cutting the first bonding surface of the bonding pad 111 or the second bonding surface of the support post 112 in the first direction. In this case, the cross section of the columnar structure is as illustrated in FIG. 22, in which a direction pointed to by the arrow is the extension direction of the connection beam. The plurality of columnar structures may also be obtained through cutting the first bonding surface of the bonding pad 111 or the second bonding surface of the support post 112 in the second direction. In this case, the cross section of the columnar structure is as illustrated in FIG. 23, in which a direction pointed to by the arrow is a direction perpendicular to the extension direction of the connection beam. The plurality of columnar structures may also be obtained through cutting the first bonding surface of the bonding pad 111 or the second bonding surface of the support post 112 in the first direction and the second direction. In this case, the cross section of the columnar structure is as illustrated in FIG. 24. The first direction described above may be the extension direction of the connection beam. The second direction described above may be at the predetermined angle to the first direction, e.g., at an angle of 45°, 60°, 90°, or the like, which may be designed as desired.

In some embodiments, the cross section of the above-mentioned columnar structure is any one of an elongate shape, a circular shape, an elliptical shape, and a polygonal shape. For example, in the embodiment illustrated in FIG. 24, the cross section of the columnar structure is of a quadrilateral shape, while in the embodiment illustrated in FIG. 25, the cross section of the columnar structure is of a circular shape. The above illustrations are for illustrative purposes.

In the above embodiments of the present disclosure, as an example, a description is made mainly with the fixing pile adopted by the connection assembly. It is conceivable for those skilled in the art that a same technical problem may be faced in other cases of using the fixing pile on the MEMS. The same technical problem can be solved by the fixing pile according to the above-mentioned embodiments illustrated in FIG. 16 to FIG. 25 with a same technical effect achieved.

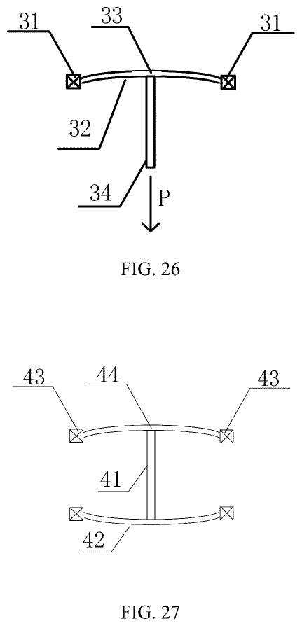

The connection assembly according to the above-mentioned embodiments may function as an extension spring capable of providing a tensile restoring force when stretched. Also, the connection assembly structure according to the above-mentioned embodiments also functions as a torsion spring. That is, when the connection beam in the connection assembly is twisted under a force, a corresponding torsion restoring force is also provided. FIG. 26 is a schematic structural view of a spring according to an embodiment of the present disclosure. As illustrated in FIG. 26, the spring includes two fixing piles 31 arranged opposite to each other and at least one connection beam 32 arranged between the two fixing piles 31. Each of the at least one connection beam 32 at least includes a first bending portion 33. In addition, the spring further includes a connection rod 34 connected to a middle of the first bending portion 33. The first bending portion 33 protrudes in a direction away from the connection rod 34.

As illustrated in FIG. 26, the spring manufactured by using the connection assembly can improve the tensile restoring force. For example, the spring can provide the tensile restoring force when subjected to a tensile force P along a plane where the connection beam is located. However, the spring can provide a torsion restoring force when subjected to a torsion force and twisted around the connection line of the two fixing piles 31. In normal cases, a force exerted on the connection assembly is a resultant force of the above-mentioned tensile force and the above-mentioned torsion force. In this case, the connection assembly, as a spring, can provide both the tensile restoring force and the torsion restoring force. The spring according to the embodiments of the present disclosure also has the technical advantages of the connection assembly according to any of the above-mentioned embodiments. Not only can the spring be less likely to be fractured during the large displacement, but also the coefficient of recovery of the spring also includes the even-order non-linear term. Therefore, the spring has a wide application range. For example, the spring can be applied to the scanning mirror. An illustration of the connection assembly in the spring according to the embodiment illustrated in FIG. 26 is only an example. Reference to a specific design structure of the connection assembly can be made to relevant descriptions of any of the above embodiments of the connection assembly in FIG. 6 to FIG. 14.

In some embodiments, the fixing pile 31 of the spring is structured to include a bonding pad integrally formed with the connection beam and a support post formed at a substrate of the MEMS. The bonding pad and the support post are bonded as an integral structure. A plurality of columnar structures are formed at a first bonding surface of the bonding pad close to the support post, and/or a plurality of columnar structures are formed at a second bonding surface of the support post close to the bonding pad.

In the embodiment, each of the plurality of columnar structures has a cross section that may be of any one of an elongate shape, a circular shape, an elliptical shape, and a polygonal shape. A shape of the cross section does not affect strength and stability of a bonding interface between the bonding pad and the support post.

In some embodiments, the plurality of columnar structures are obtained through cutting in a first direction, and/or the plurality of columnar structures are obtained through cutting in a second direction. The first direction is an extension direction of the connection beam. The second direction is at a predetermined angle to the first direction.

For a specific structure of the fixing pile 31, reference can be made to the embodiments illustrated in FIG. 15 to FIG. 25 above. In some embodiments, two connection assembly structures may be connected as one spring assembly, in addition to using the above-mentioned separately arranged connection assembly as the spring. FIG. 27 is a schematic structural view of a spring assembly according to an embodiment of the present disclosure. In an exemplary embodiment of the present disclosure, as illustrated in FIG. 27, the spring assembly includes a connection rod 41 and two connection beams 42 arranged at two ends of the connection rod 41, respectively. Each of two ends of each connection beam 42 is provided with a fixing pile 43. The fixing pile 43 can be fixed to other structures of the MEMS system. Each connection beam 42 at least includes a first bending portion 44 protruding in a direction away from the connection rod 41. Like the spring according to the above-mentioned embodiments, the spring assembly according to the embodiments of the present disclosure also has technical advantages of the connection assembly according to any of the above-mentioned embodiments. Not only can the spring assembly be less likely to be fractured during a large displacement, but also a coefficient of recovery of the spring assembly also includes an even-order non-linear term. Therefore, the spring assembly has a wide application range. For example, the spring assembly can be applied to the scanning mirror. An illustration of the two connection assemblies in the spring assembly according to the embodiment illustrated in FIG. 27 is only an example. Reference to specific design structures of the two connection assemblies can be made to relevant descriptions of any of the above embodiments of the connection assembly in FIG. 6 to FIG. 14.

In some embodiments, the above-mentioned fixing pile 43 is structured to include a bonding pad integrally formed with the connection beam and a support post formed at a substrate of the MEMS. The bonding pad and the support post are bonded as an integral structure. A plurality of columnar structures are formed at a first bonding surface of the bonding pad close to the support post, and/or a plurality of columnar structures are formed at a second bonding surface of the support post close to the bonding pad.

In the embodiment, each of the plurality of columnar structures has a cross section that may of any one of an elongate shape, a circular shape, an elliptical shape, and a polygonal shape. A shape of the cross section does not affect strength and stability of a bonding interface between the bonding pad and the support post.

In some embodiments, the plurality of columnar structures are obtained through cutting in a first direction, and/or the plurality of columnar structures are obtained through cutting in a second direction. The first direction is an extension direction of the connection beam. The second direction is at a predetermined angle to the first direction.

For a specific structure of the fixing pile 43, reference can be made to the embodiments illustrated in FIG. 15 to FIG. 25 above.

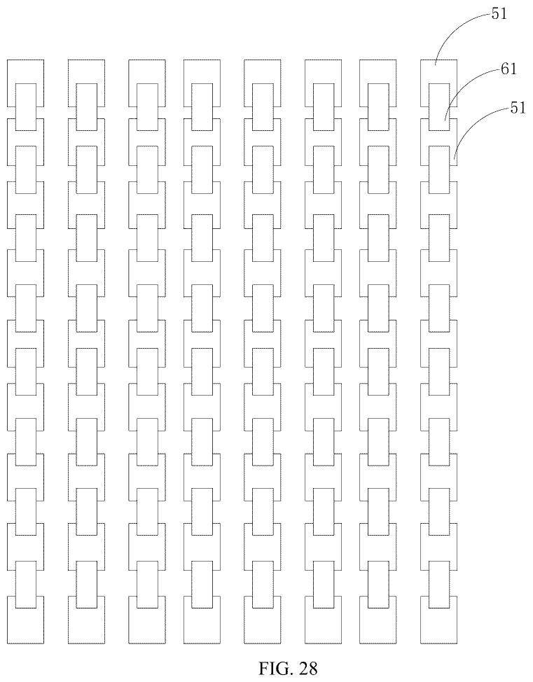

The embodiments of the present disclosure further provide a scanning mirror using the spring assembly according to any of the above-mentioned embodiments. FIG. 28 is a schematic structural view of a scanning mirror according to an embodiment of the present disclosure. As illustrated in FIG. 28, the scanning mirror includes torsion springs 51 arranged in an array on a MEMS. A coupling spring 61 (i.e., the above-mentioned connection assembly) is arranged between any two adjacent torsion springs 51 of the torsion springs 51. Two ends of the coupling spring 61 are connected to the two adjacent torsion springs 51, respectively. In response to the two adjacent torsion springs 51 being twisted, the coupling spring 61 is stretched to provide a torque that is non-linearly recovered.

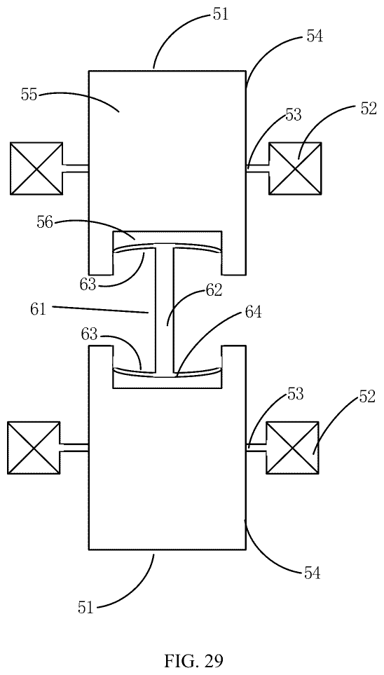

For a structure formed in the above-mentioned manner that the two ends of the coupling spring 61 are connected to the two adjacent torsion springs 51, respectively, a detailed illustration can be found in FIG. 29. As illustrated in FIG. 29, each torsion spring 51 includes two fixing components 52 arranged opposite to each other and a beam structure 53 arranged between the two fixing components 52. The beam structure 53 is provided with a first connection plate 54. The two ends of the coupling spring 61 in a stretching direction are connected to two first connection plates 54 (the above-mentioned fixing piles 11 are defined by the first connection plates 54) of the two adjacent torsion springs 51, respectively. A reflection mirror 55 is arranged at a surface of the first connection plate 54.

Each of the two first connection plates 54 has an opening 56 close to the coupling spring 61. The coupling spring 61 includes a connection rod 62 and two connection beams 63 arranged at two ends of the connection rod 62, respectively. The connection rod 62 is connected to the two first connection plates 54 arranged at two sides of the opening 56 by the two connection beams 63, respectively. Each clamping beam 63 at least includes a first bending portion 64 protruding in a direction away from the connection rod 62. With the scanning mirror according to the embodiments of the present disclosure, the coupling spring is arranged between any two adjacent torsion springs. That is, a plurality of spring assemblies connected to each other are formed. Each coupling spring 61 is equivalent to one controllable non-linear spring. In this case, other drive components can be used to drive the torsion springs to twist and to drive the reflection mirror to twist. Then, the coupling spring 61 is recovered through a non-linear restoring force. Therefore, the above-mentioned actions are periodically completed, realizing that all the light reflected by the reflection mirrors is scanned in a predetermined region to achieve an effect of one overall scanning mirror. Further, the coupling spring 61 according to the embodiments of the present disclosure includes two connection assembly structures according to the above-mentioned embodiments. In an exemplary embodiment of the present disclosure, the first bending portion 64 is at least included in the connection beam 63 in the coupling spring 61, which is equivalent to the connection assembly according to any of the above-mentioned embodiments. Details of the coupling spring 61 can be referred to implementations and technical effects according to the above-mentioned embodiments illustrated in FIG. 6 to FIG. 14.

In some embodiments, a middle of the connection rod 62 in FIG. 29 may also be supported by a structure similar to the beam structure 52 and the fixing pile 53, which is optional with the technical solution provided in FIG. 29.

In the embodiments of the present disclosure, a plurality of torsion springs 51 are arranged at the MEMS in the array. That is, torsion springs 51 in a plurality of rows and columns can be included. In addition, the reflection mirror 55 is arranged at the surface of the first connection plate 54 of each torsion spring 51, in such a manner that the large-area reflection mirror can be formed by the plurality of small-area reflection mirrors 55 mentioned above.

In some embodiments, the above-mentioned fixing component 52 may have a same structure as the fixing pile 11. Reference can be made to description of the embodiments illustrated in FIG. 15 to FIG. 25, and thus details thereof will be omitted here.

In some embodiments, a drive component may further be provided. The drive component is configured to drive the torsion springs arranged in the array to twist synchronously. Driving the torsion springs arranged in the array to twist synchronously is equivalent to driving the large-area scanning mirror to rotate, realizing that light reflected from the large-area scanning mirror can be scanned in a predetermined region. Operation principles and a set position of the drive component are not limited in the embodiments of the present disclosure. The drive component may include various forms of drive components. For example, the drive component may be independently arranged at a MEMS substrate, or may be arranged at the MEMS substrate and the first connection plate. In addition, to save a space and to reserve a space for the reflection mirror at the first connection plate, other members may be arranged below the first connection plate as a whole.

In addition, the above-mentioned drive component may include a plurality of drive units. Each of the plurality of drive units is arranged corresponding to a respective torsion spring of the torsion springs and is configured to drive the respective torsion spring to twist. Depending on operation principles, the drive unit includes, but is not limited to, any one of the electrostatic drive unit, the electrothermal drive unit, the capacitive drive unit, or the piezoelectric drive unit. By arranging any one of the above-mentioned drive units at the MEMS, the technical effect of driving the torsion spring to twist can be achieved. According to the embodiments of the present disclosure, the coupling spring can be made small in size and more space be reserved for accommodating the first connection plate, in such a manner that the area of the reflection mirror at the first connection plate is enlarged, enlarging the effective reflection area of the MEMS scanning mirror.

In addition, in some embodiments, to enlarge the area of each reflection mirror, and to enlarge the area of the scanning mirror that is ultimately formed, the above-mentioned first connection plate may be expanded in a column direction to enable the coupling spring to be located in a gap formed by the above-mentioned first connection plate. In this case, a vast majority of the area of the surface of the entire MEMS system is occupied by the scanning mirror that is ultimately formed to further enlarge the effective reflective area of the MEMS scanning mirror, and to improve uniformity of reflected light.

Further, in another embodiment, for the torsion springs 51 in different columns in FIG. 28, the torsion springs 51 in one column may be connected to the torsion springs 51 in another column adjacent to the one column and located in a same row. That is, as in the embodiment illustrated in FIG. 29, any first connection plate 54 is connected to the first connection plate 54 of another torsion spring 51 in the same row and an adjacent column, as long as the fixing component 52 is avoided. Such an implementation can further enlarge the area of the reflection mirror at the first connection plate 54 to further enlarge the effective reflective area of the MEMS scanning mirror, and to improve the uniformity of the reflected light.

In addition, in the embodiments of the present disclosure, the connection beam in the coupling spring includes the first bending portion. The first bending portion protrudes in a direction away from the connection rod. Since the first bending portion is arranged, the tensile stress of the connection beam is unlikely to rapidly increase even when the large displacement occurs in the direction opposite to the protrusion direction of the first bending portion. Therefore, the first bending portion is prevented from fracturing the connection beam in response to rapidly reaching the fracture stress of silicon, enhancing the resistance to fracture of the first bending portion. In addition, such a design also causes the coefficient of recovery of the connection beam to include the second-order non-linear coefficient of recovery, which is conducive to ultimately realizing the controllable non-linear spring demanded by the technical solutions of the present disclosure and facilitates subsequent synchronous control of synchronous torsion of the plurality of reflection mirrors mentioned above.

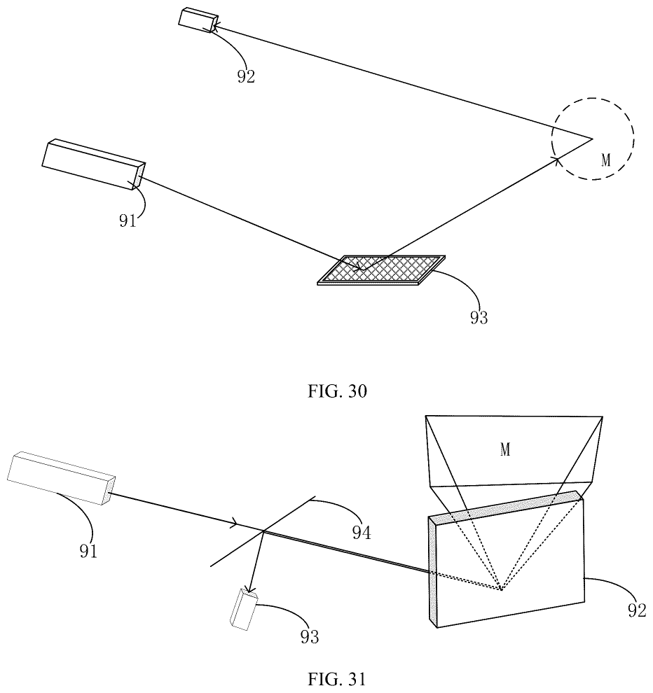

The LiDAR system is further provided according to the embodiments of the present disclosure. The LiDAR system is capable of realizing light detection and ranging. FIG. 30 is a schematic structural view of a LiDAR system according to an embodiment of the present disclosure. As illustrated in FIG. 30, the LiDAR system includes a light source 91, a photodetector 92, and the above-mentioned scanning mirror 93. A laser beam emitted by the light source 91 is reflected to a target region M by the above-mentioned scanning mirror 93. In addition, the photodetector 92 is configured to receive at least part of reflected light from the target region M and convert the at least part of the reflected light into an electrical signal. Further, a processor may be provided. The processor is configured to obtain a laser point cloud from the target region based on the electrical signal output by the photodetector 92. The light detection and ranging can be realized based on the above-mentioned laser point cloud.

FIG. 31 is a schematic structural view of another LiDAR system according to an embodiment of the present disclosure. As illustrated in FIG. 31, the LiDAR system also includes the light source 91, the photodetector 92, and the scanning mirror 93, with a difference that, unlike a paraxial technical solution adopted in FIG. 13, a coaxial technical solution is adopted in the embodiment illustrated in FIG. 31. In an exemplary embodiment of the present disclosure, the LiDAR system further includes a beam splitter 94. In this way, the laser beam emitted by the light source 91 is reflected by the scanning mirror 93 to the target region M after sequentially passing through the beam splitter 94 and the scanning mirror 93, for scanning the target region M. The at least part of the reflected light from the target region M may pass through the above-mentioned scanning mirror 93 to the beam splitter 94. The reflected light is directed to the photodetector 92 by the beam splitter 94 to enable the photodetector 92 to convert the reflected light into an electrical signal. Further, the processor can be configured to obtain the laser point cloud from the target region based on the electrical signal output from the photodetector, where the processor is further provided in the system, to realize the light detection and ranging. The above-mentioned light source 91, the photodetector 92, and the beam splitter 94 according to this embodiment may also form a laser transceiver module to realize laser emission and detection.

Due to the use of the scanning mirror according to the above-mentioned embodiments, the LiDAR system according to the embodiments of the present disclosure has corresponding technical effects and advantages. In addition, the above-mentioned LiDAR system can be applied to a vehicle. A solution of forming the scanning mirror by the plurality of small-area reflection mirrors is conducive to improving a vibration-resistant capability of the LiDAR system during vehicle operation.

In addition, in the LiDAR system according to the embodiments of the present disclosure, synchronous torsion of individual reflection mirrors in the scanning mirror enables scanning to be performed after the laser beam is reflected to the target region M. This scanning method, however, performs scanning in a predetermined direction. For enlarging an area of the target region M, the scanning also needs to be performed in a vertical direction. That is, for an XY coordinate system in the target region M, scanning along an X-axis rather than a Y-axis can be achieved using the technical solutions according to the embodiments of the present disclosure. Therefore, in some embodiments, the drive component may further be provided, which can be configured to directly drive the scanning mirror as a whole to move back and forth in a reciprocating manner to achieve scanning along the Y-axis. The above-mentioned drive component may be a drive motor. The drive motor is configured to directly drive, using an output shaft, the scanning mirror to reciprocate, to ultimately realize scanning performed by the reflected light from the scanning mirror along the Y-axis. In this case, the output shaft of the drive motor usually needs to be able to steer in time, switching between a forward rotation and a reverse rotation. Or, in an alternative technical solution, a movement adjustment member may be provided, which is capable of converting a continuous circular movement of the output shaft of the drive motor into a cyclic reciprocating movement. The scanning mirror is driven by the movement adjustment member to perform a periodic reciprocating movement, to ultimately realize the scanning performed by the reflected light from the scanning mirror along the Y-axis.

For the scanning mirror, according to the embodiments of the present disclosure, scanning realized by driving each small-area scanning mirror inside the scanning mirror can be at a relatively high scanning frequency. That is, rapid scanning along the X-axis in the target region M is achieved. However, scanning realized by driving, using the drive motor, the entire scanning mirror can be at a relatively low scanning frequency. That is, low scanning along the Y-axis in the target region M is achieved.

Terms such as “first” and “second” in the specification of the present disclosure and the appended claims are used only to distinguish between similar objects, rather than to describe a particular order or sequence. It should be understood that the data as used can be interchanged where appropriate, to enable the embodiments of the present disclosure described herein to be implemented in an order other than that illustrated or described herein. Also, the objects distinguished by the terms such as “first” and “second” are usually objects of the same type. The quantity of the objects is not limited. For example, one or a plurality of first objects may be provided. In addition, “and/or” throughout the specification and appended claims indicates at least one of the objects associated with “and/or”. The character “/” generally indicates that the associated objects before and after the character are in an “or” relationship.

In the description of the present disclosure, it should be understood that, the orientation or the position indicated by terms such as “center”, “longitudinal”, “lateral”, “length”, “width”, “thickness”, “over”, “below”, “front”, “rear”, “left”, “right”, “vertical”, “horizontal”, “top”, “bottom”, “inner”, “outer”, “clockwise”, “anti-clockwise”, “axial”, “radial”, and “circumferential” should be construed to refer to the orientation and the position as shown in the drawings, and is only for the convenience of describing the present disclosure and simplifying the description, rather than indicating or implying that the pointed device or element must have a specific orientation, or be constructed and operated in a specific orientation, and therefore cannot be understood as a limitation of the present disclosure.

In the description of the present disclosure, “first feature” and “second feature” may include one or more of these features.

In the description of the present disclosure, “plurality” means two or more.

In the description of the present disclosure, the first feature “on” or “under” the second feature may mean that the first feature is in direct contact with the second feature, or the first and second features are in indirect contact through another feature between them.

In the description of the present disclosure, the first feature “above” the second feature means that the first feature is directly above or obliquely above the second feature, or simply means that the level of the first feature is higher than that of the second feature.

Reference throughout this specification to “an embodiment”, “some embodiments”, “illustrative embodiments”, “an example”, “a specific example”, or “some examples” means that a particular feature, structure, material, or characteristic described in connection with the embodiment or example is included in at least one embodiment or example of the present disclosure. The appearances of the above phrases in various places throughout this specification are not necessarily referring to the same embodiment or example. Further, the particular features, structures, materials, or characteristics may be combined in any suitable manner in one or more embodiments or examples.

Although embodiments of the present disclosure have been illustrated and described, it is conceivable for those skilled in the art that various changes, modifications, replacements, and variations can be made to these embodiments without departing from the principles and spirit of the present disclosure. The scope of the present disclosure shall be defined by the claims as appended and their equivalents.

What is claimed is:

1. A connection assembly for a MEMS, comprising:
two fixing piles arranged opposite to each other; and
at least one connection beam arranged between the two fixing piles, each of the at least one connection beam at least comprising a first bending portion.

2. The connection assembly according to claim 1, wherein the first bending portion extends from one fixing pile of the two fixing piles to the other fixing pile of the two fixing piles.

3. The connection assembly according to claim 1, wherein each of the at least one connection beam further comprises a first straight segment and a second straight segment that have a same length, each of the at least one connection beam being connected to the two fixing piles through the first straight segment and the second straight segment, respectively.

4. The connection assembly according to claim 1, wherein each of the at least one connection beam further comprises a second bending portion and a third bending portion, each of the at least one connection beam being connected to the two fixing piles through the second bending portion and the third bending portion, respectively.

5. The connection assembly according to claim 4, wherein:
a curvature of the second bending portion and a curvature of the third bending portion are the same and smaller than a curvature of the first bending portion; and/or
the second bending portion and the third bending portion have a bending direction opposite to a bending direction of the first bending portion.

6. The connection assembly according to claim 1, wherein:
the at least one connection beam comprises two connection beams arranged symmetrically with respect to a center plane, and the two connection beams sharing the two fixing piles; or
each of the two fixing piles comprises two sub-fixing piles, the two sub-fixing piles being configured to support the two connection beams.

7. The connection assembly according to claim 1, further comprising a connection rod connected to the first bending portion, the first bending portion protruding in a direction away from the connection rod.

8. The connection assembly according to claim 7, wherein the connection rod has two ends each connected to a corresponding connection beam of the at least one connection beam.

9. The connection assembly according to claim 1, further comprising a mass block, the connection beam being configured to support the mass block.

10. The connection assembly according to claim 1, wherein each of the two fixing pile comprises:
a bonding pad; and
a support post formed at a substrate of the MEMS, wherein:
the bonding pad, the at least one connection beam and the support post are formed as one piece, and a plurality of columnar structures are formed at a first bonding surface of the bonding pad close to the support post, and/or a plurality of columnar structures are formed at a second bonding surface of the support post close to the bonding pad.

11. The connection assembly according to claim 10, wherein the plurality of columnar structures are obtained through cutting in a first direction, and/or the plurality of columnar structures are obtained through cutting in a second direction, the first direction being an extension direction of the at least one connection beam, and the second direction being at a predetermined angle to the first direction.

12. A scanning mirror, comprising torsion springs arranged in an array on a MEMS, a connection assembly being arranged between any two adjacent torsion springs of the torsion springs, the two adjacent torsion springs being connected by the connection assembly, and in response to the two adjacent torsion springs being twisted, the connection assembly being stretched to provide a torque that is non-linearly recovered, wherein:
each of the torsion springs comprises two fixing components arranged opposite to each other and a beam structure arranged between the two fixing components, the beam structure being provided with a first connection plate, the two ends of the connection assembly in a stretching direction being connected to two first connection plates of the two adjacent torsion springs, respectively, and a reflection mirror being arranged at a surface of the first connection plate;
each of the two first connection plates has an opening formed at an end close to a connection assembly, the connection assembly comprising two fixing piles arranged opposite to each other, at least one connection beam arranged between the two fixing piles, and a connection rod;
wherein each of the at least one connection beam at least comprising a first bending portion, the connection rod being connected to the two first connection plates arranged at two sides of the opening by the two connection beams, respectively; and
the scanning mirror further comprises a drive component configured to drive the torsion springs arranged in the array to twist synchronously.

13. The scanning mirror according to claim 12, wherein the first bending portion extends from one fixing pile of the two fixing piles to the other fixing pile of the two fixing piles.

14. The scanning mirror according to claim 12, wherein each of the at least one connection beam further comprises a first straight segment and a second straight segment that have a same length, each of the at least one connection beam being connected to the two fixing piles through the first straight segment and the second straight segment, respectively.

15. The scanning mirror according to claim 12, wherein each of the at least one connection beam further comprises a second bending portion and a third bending portion, each of the at least one connection beam being connected to the two fixing piles through the second bending portion and the third bending portion, respectively.

16. The scanning mirror according to claim 15, wherein:
a curvature of the second bending portion and a curvature of the third bending portion are the same and smaller than a curvature of the first bending portion; and/or
the second bending portion and the third bending portion have a bending direction opposite to a bending direction of the first bending portion.

17. The scanning mirror according to claim 12, wherein:
the at least one connection beam comprises two connection beams arranged symmetrically with respect to a center plane, and the two connection beams sharing the two fixing piles; or
each of the two fixing piles comprises two sub-fixing piles, the two sub-fixing piles being configured to support the two connection beams.

18. The scanning mirror according to claim 12, wherein the connection assembly further comprises a connection rod connected to the first bending portion, the first bending portion protruding in a direction away from the connection rod.

19. The scanning mirror according to claim 18, wherein the connection rod has two ends each connected to a corresponding connection beam of the at least one connection beam.

20. A LiDAR system, comprising:
a light source;
a photodetector;
a processor; and
the scanning mirror according to claim 12, wherein:
a laser beam emitted by the light source is reflected to a target region by the scanning mirror;
the photodetector is configured to receive at least part of reflected light from the target region and convert the at least part of the reflected light into an electrical signal; and
the processor is configured to obtain a laser point cloud from the target region based on the electrical signal.
